(19) United States
(12) Patent Application Publication
(10) Pub. No.: US 2012/0161323 A1
(43) Pub. Date: Jun. 28, 2012

(54) SUBSTRATE FOR PACKAGE AND METHOD FOR MANUFACTURING THE SAME

(75) Inventors: Yoon Su KIM, Gangwon-do (KR); Seon Hee MOON, Seoul (KR); Seung Wan SHIN, Gyunggi-do (KR); Young Do KWEON, Seoul (KR)

(73) Assignee: SAMSUNG ELECTRO-MECHANICS CO., LTD., Gyunggi-do (KR)

(21) Appl. No.: 13/040,741

(22) Filed: Mar. 4, 2011

(30) Foreign Application Priority Data
Dec. 24, 2010 (KR) 10-2010-0134736

(51) Int. Cl. H01L 23/48; H01L 21/28

(52) U.S. Cl. 257/753; 438/654; 257/E23.01; 257/E21.158

(57) ABSTRACT

Disclosed herein are a substrate for a package and a method for manufacturing the same. The substrate for the package according to the present invention includes: a base substrate; a photosensitive insulating layer formed on one surface of the base substrate and having a roughness formed on a surface thereof; and a seed layer formed on one surface of the photosensitive insulating layer.

### CROSS REFERENCE TO RELATED APPLICATION

This application claims the benefit of Korean Patent Application No. 10-2010-0134736, filed on Dec. 24, 2010, entitled “Substrate for Package and Method for Manufacturing The Same” which is hereby incorporated by reference in its entirety into this application.

### BACKGROUND OF THE INVENTION

1. Technical Field

The present invention relates to a substrate for a package and a method for manufacturing the same.

2. Description of the Related Art

Recently, as slimness, lightness and smallness of a substrate functioning as an interposer between a substrate and an electronic device has advanced at a high speed, a seed layer for forming patterns is formed by using sputtering for a substrate capable of realizing high density and fine pattern.

However, the seed layer formed by using the sputtering causes a problem of decreasing the adhesion with an insulating layer, and thus, it is urgently needed to solve this problem.

### SUMMARY OF THE INVENTION

The present invention has been made in an effort to provide a substrate for a package and a method for manufacturing the same capable of improving adhesion between a seed layer and an insulating layer by forming a specific pattern of roughness on a surface of a photosensitive insulating layer.

Further, the present invention has been made in an effort to provide a method for manufacturing a substrate for a package capable of forming a specific pattern of a roughness and via holes at the same time.

According to a preferred embodiment of the present invention, there is provided a substrate for a package, including: a base substrate; a photosensitive insulating layer formed on one surface of the base substrate and having a roughness formed on a surface thereof; and a seed layer formed on one surface of the photosensitive insulating layer.

The insulating layer may further include via holes formed for exposing connection pads on the base substrate.

The roughness may have a predetermined pattern, and may be formed by photolithography including exposing and developing processes.

The seed layer may include a first seed layer and a second seed layer formed on the first seed layer. The first seed layer may be a titanium (Ti) layer, a titanium-tungsten (TiW) layer, a titanium nitride (TiN) layer, a chromium (Cr) layer, a nickel (Ni) layer, an aluminum (Al) layer or an alloy layer thereof. The second seed layer being a copper (Cu) layer, a nickel (Ni) layer, a nickel vanadium (NiV) layer, or an alloy layer thereof.

The substrate for a package may further include a circuit pattern layer formed on the seed layer.

According to a preferred embodiment of the present invention, there is provided a method for manufacturing a substrate for a package, including: preparing a base substrate; forming a photosensitive insulating layer on the base substrate; forming a roughness on a surface of the photosensitive insulating layer; and forming a seed layer on the surface of the photosensitive insulating layer on which the roughness is formed.

The forming the roughness may include forming via holes for exposing connection pads of the base substrate.

The formed roughness may have a predetermined pattern.

The forming the roughness on the surface of the insulating layer may include disposing a mask having a pattern over the insulating layer; and forming the roughness according to the pattern on the surface of the insulating layer by exposing and developing processes.

The pattern may include a pattern for forming the roughness and a pattern for forming the via holes, and the pattern for forming the roughness and the pattern for forming the via holes may have different light transmittances.

The seed layer may include a first seed layer and a second layer formed on the first seed layer. The first seed layer may be a titanium (Ti) layer, a titanium-tungsten (TiW) layer, a titanium nitride (TiN) layer, a chromium (Cr) layer, a nickel (Ni) layer, an aluminum (Al) layer or an alloy layer thereof. The second seed layer may be a copper (Cu) layer, a nickel (Ni) layer, a nickel vanadium (NiV) layer, or an alloy layer thereof. Also, the seed layer may be formed by sputtering.

The method may further include forming a circuit pattern layer on the seed layer, after the forming the seed layer.

### BRIEF DESCRIPTION OF THE DRAWINGS

FIG. 1 is a cross sectional view showing a structure of a substrate for a package according to a preferred embodiment of the present invention;

FIGS. 2 to 8 show a process flowchart for explaining a manufacturing method of a substrate for a package according to a preferred embodiment of the present invention;

FIG. 9 is a cross sectional view for showing a structure of a mask used in a manufacturing method of a substrate for a package according to a preferred embodiment of the present invention and a process of forming a roughness on an insulating layer by using the mask; and

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second” and so on are used to distinguish one element from another element, and the elements are not defined by the above terms.

Hereinafter, preferred embodiments of the present invention will be described in detail with reference to the accompanying drawings.

Substrate for Package

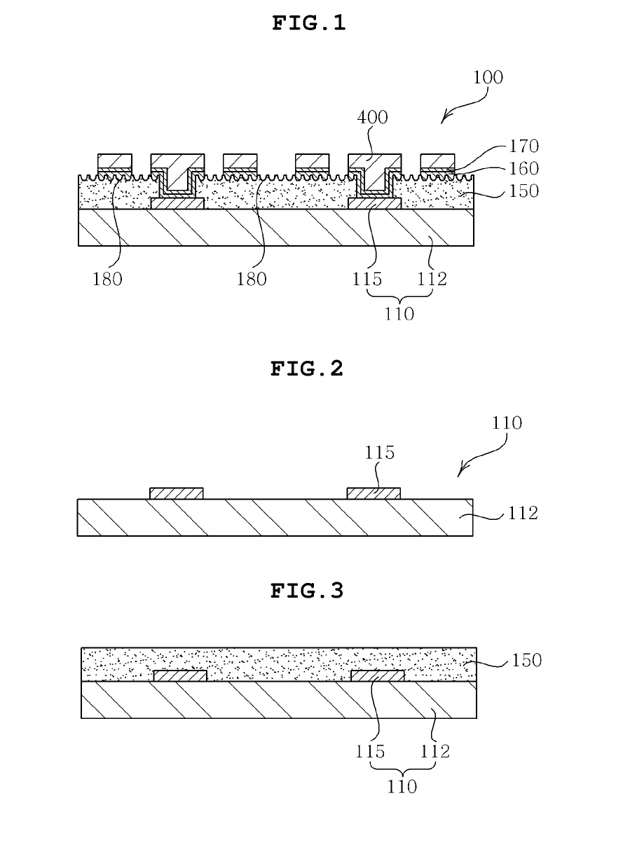

FIG. 1 is a cross sectional view showing a substrate for a package according to a preferred embodiment of the present invention.

Referring to FIG. 1, a substrate 100 for a package according to the present invention includes a base substrate 110, an insulating layer 150, seed layers 160 and 170, and a circuit pattern layer 400.

The base substrate 110 may be a circuit board in which circuits of one or more layers, including connection pads 115, are formed on an insulation layer. Although a detailed constitution of an inner circuit is omitted in the figure for convenience of explanation, those skilled in the art will fully appreciate that a common circuit board, when circuits of one or more layers are formed on an insulation layer, is usable as the base substrate 110.

The connection pads 115, which are electrically connected to the inner circuit, are formed on an upper surface of the base substrate 110. An insulating layer 150 is formed on the upper surface of the base substrate 110 such that the connection pads 115 are exposed.

The insulating layer 150 is a layer for protecting the surface of the base substrate 110. A photosensitive resin is used for the insulating layer in the present invention. The photosensitive resin may be, but not limited to epoxy resin where rubber particles are mixed, polyimide (PI), polybenzooxazole (PBO), or benzocyclobutene (BCB).

A roughness 180 is formed on the insulating layer 150 in the present invention. Herein, the roughness 180 may be formed in a predetermined size and a predetermined pattern. Preferably, the roughness may be formed in a micrometer (Lan) level, but not particularly limited thereto.

As such, the roughness 180 having the predetermined size and pattern may be formed on the insulating layer 150 to improve adhesion between the surface of the insulating layer 150 and the first seed layer 160 to be vacuum-deposited in a subsequent process.

Also, in addition to the roughness 180, via holes 190 may be formed in the insulating layer 150 to expose the connection pads 115 of the base substrate 110.

A method of forming the roughness 180 and the via holes 190 will be explained in a manufacturing method to be described below.

The seed layers 160 and 170 may have a first seed layer 160 and a second seed layer 170, which are formed in order. The first seed layer 160 works as a layer of improving the adhesion between the connection pads 115 of the base substrate 110 and the insulating layer 150 and the second seed layer 170. The first seed layer 160 may be a titanium (Ti) layer, a titanium-tungsten (TiW) layer, a titanium nitride (TiN) layer, a chromium (Cr) layer, a nickel (Ni) layer, an aluminum (Al) layer or an alloy layer thereof. Also, the second seed layer 170 works as a layer functioning as a seed for the circuit pattern layer 400, which is formed in a subsequent semiconductor process. The second seed layer 170 may be a copper (Cu) layer, a nickel (Ni) layer, a nickel vanadium (NiV) layer, or an alloy layer thereof.

Preferably, the first seed layer 160 may be a titanium (Ti) layer and the second seed layer 170 may be a copper (Cu) layer, but not particularly limited thereto.

The circuit pattern layer 400 is a circuit layer formed on the connection pads 115 of the base substrate 110 and the insulating layer 150 exposing the connection pads 115.

The circuit pattern layer 400 may be formed by sputtering, electroplating, or electrolytic plating, but not particularly limited thereto. The circuit pattern layer 400 may be a copper (Cu) layer, a nickel (Ni) layer, a palladium (Pd) layer, a silver (Ag) layer, or an alloy layer thereof, but not particularly limited thereto.

Manufacturing Method of Substrate for Package

FIGS. 2 to 8 show a process flowchart for explaining a manufacturing method of a substrate for a package according to a preferred embodiment of the present invention.

Referring to FIG. 2, a base substrate 110 having connection pads 115 is prepared. Herein, the connection pads 115 may be formed of aluminum (Al) or copper (Cu), but not particularly limited thereto.

Referring to FIG. 3, an insulating layer 150 is formed on the base substrate 110. The insulating layer 150 is for protecting an upper surface of the base substrate 110. A photosensitive resin may be used for the insulating layer 150 in the present invention.

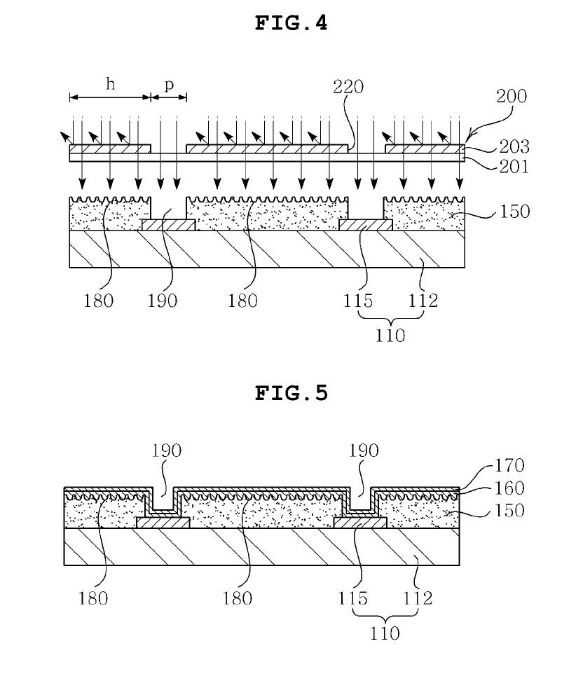

Referring to FIG. 4, a mask 200 is disposed over the insulating layer 150, and then a roughness is formed by using a photolithography including exposing and developing processes.

Herein, the mask 200 is constituted of patterns, which are formed on a transparent plate 201 by using a shielding film 203. Materials for forming the shielding film 203 may be chromium based materials including chromium (Cr), chromium oxide (Cr2O3), chromium nitride (CrN) and chromium carbide (Cr3C2), but not particularly limited thereto.

The mask 200 may include a region having such a thickness that the shielding film 203 is capable of transmitting only half the light, for example, a semi-transmission region h, and a region where the shielding film 203 is not formed, for example, a transmission region p. Besides, although not shown in FIG. 4, the mask 200 may further include a shielding region having such a thickness that the shielding film 203 is capable of shielding the light completely.

This will be described with reference to FIG. 9 below. A shielding region a for shielding the light completely, a first semi-transmission region c for transmitting only half the light, and a second semi-transmission region d for transmitting the light less than the first semi-transmission region c are formed on the transparent plate 201 of the mask 200 by using a chromium based shielding film

Herein, the shielding region a, the first semi-transmission region c, and the second semi-transmission region d may be formed by controlling the forming thickness of the chromium based materials, but not limited thereto, and also may be formed in any one of methods known in the art.

When the mask 200 manufactured as the above is disposed over a photosensitive resin (PR), and then the exposing and developing processes are performed, it is possible to form patterns of various depth values at the same time, as shown in FIG. 9. This is why the transmission amount of the light, which is transmitted through the shielding region a, the transmission region b, the first semi-transmission region c, and the second semi-transmission region, is different according to the regions.

Accordingly, as shown in FIG. 4, the mask 200 is disposed over the insulating layer 150 such that a portion of the shielding film 203, which is formed on the transparent plate 201 in a predetermined thickness by using chromium materials, is positioned over a roughness formation region h for forming the roughness on the surface of the insulating layer 150, and a transparent portion of the transparent plate 201, on which the shielding film 203 is not formed, is positioned over a via hole formation region p for forming the via holes of exposing the connection pads 115 on the base substrate 110. If a photolithographic process is performed in this condition, it is possible to form a predetermined pattern of the roughness 180 and via holes 190 on and in the insulating layer 150, respectively, at the same time.

Referring to FIG. 5, seed layers 160 and 170 are formed on the surface of the insulating layer 150 having the roughness 180 and via holes 190. The seed layers 160 and 170 include a first seed layer 160 and a second seed layer 170.

The first seed layer 160 works as a layer of improving the adhesion between the connection pads 115 of the base substrate 110 and the insulating layer 150 and the second seed layer 170. The first seed layer 160 may be a titanium (Ti) layer, a titanium-tungsten (TiW) layer, a titanium nitride (TiN) layer, a chromium (Cr) layer, a nickel (Ni) layer, an aluminum (Al) layer or an alloy layer thereof. Also, the second seed layer 170 works as a seed layer for the circuit pattern layer 400, which is formed in a subsequent semiconductor process. The second seed layer 170 may be a copper (Cu) layer, a nickel (Ni) layer, a nickel vanadium (NiV) layer, or an alloy layer thereof.

Preferably, the first seed layer 160 may be a titanium (Ti) layer and the second seed layer 170 may be a copper (Cu) layer, but not particularly limited thereto. The first seed layer 160 and the second layer 170 may be formed continuously by sputtering.

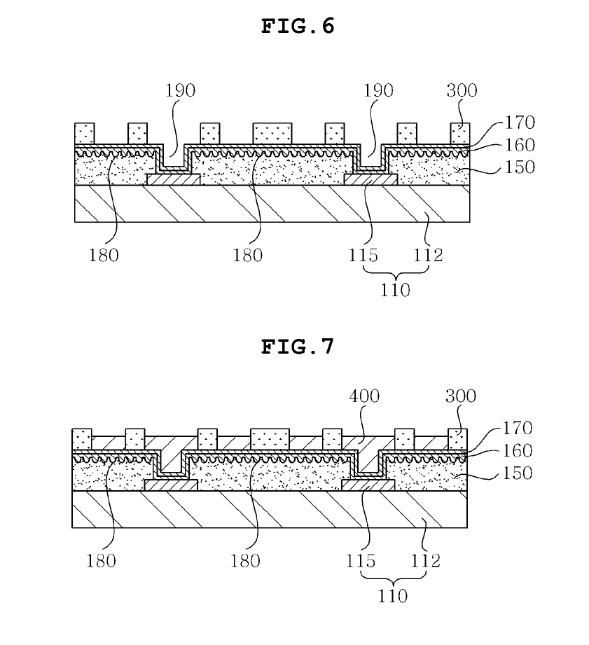

Referring to FIG. 6, a mask 300 is disposed over the second seed layer 170. The mask has a pattern for forming a circuit pattern layer, in order to form a circuit pattern layer 400 on the second seed layer 170. The mask 300 may be a photosensitive film.

Referring to FIG. 7, the circuit pattern layer 400 is formed on the second seed layer 170 exposed by the pattern. The circuit pattern layer 400 may be formed by sputtering, electroplating, or electrolytic plating, but not particularly limited thereto. When the electroplating or the electrolytic plating is performed, current may be supplied through the second seed layer 170. Also, the circuit pattern layer 400 may be a copper (Cu) layer, a nickel (Ni) layer, a palladium (Pd) layer, a silver (Ag) layer, or an alloy layer thereof, but not particularly limited thereto.

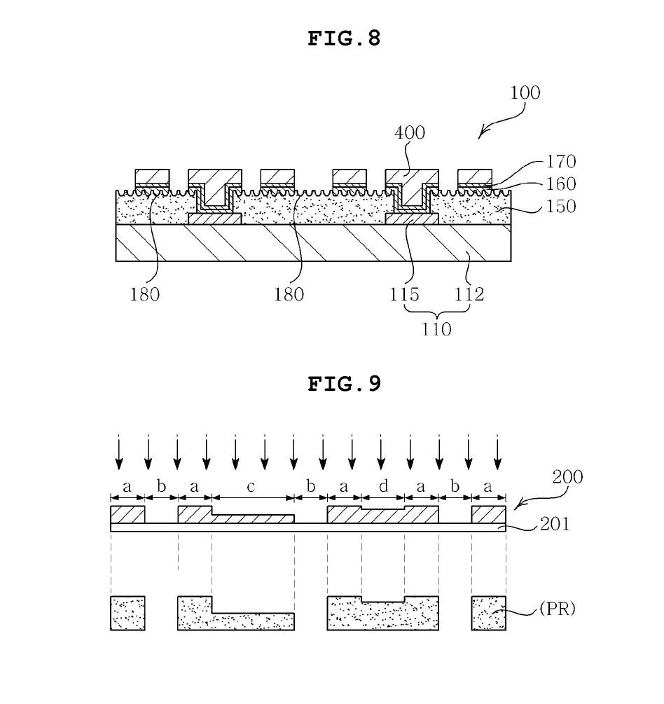

Referring to FIG. 8, the mask 300 is removed to expose the seed layers 160 and 170, and then the exposed seed layers 160 and 170 are etched by using the circuit pattern layer 400 as a mask.

As described above, according to a preferred embodiment of the present invention, when forming a photosensitive insulating layer on a base substrate, disposing a mask with various patterns having different transmittances of light over the photosensitive insulating layer, and then performing exposing and developing processes, a predetermined pattern of a roughness and via holes can be formed at the same time. In addition, as the predetermined pattern of the roughness is formed on the photosensitive insulating layer, it is possible to improve the adhesion between the seed layer and the insulating layer.

The present invention is capable of improving the adhesion between a seed layer and an insulating layer by forming a predetermined pattern of a roughness on a surface of the insulating layer.

Also, the present invention is capable of forming a roughness of a desired pattern at a desired part by forming the roughness on a photosensitive insulating layer using an exposure mask.

Also, the present invention is capable of patterns of different depth values, including a roughness and a pattern for via holes, at the same time by applying an exposure mask having patterns of different light transmittances to the photosensitive insulating layer.

Although the preferred embodiments of the present invention have been disclosed for illustrative purposes, they are for specifically explaining the present invention and thus a substrate for a package and a method for manufacturing the same according to the present invention are not limited thereto, but those skilled in the art will appreciate that various modifications, additions and substitutions are possible, without departing from the scope and spirit of the invention as disclosed in the accompanying claims

Accordingly, such modifications, additions and substitutions should also be understood to fall within the scope of the present invention.

What is claimed is:

1. A substrate for a package, comprising:
a base substrate;
a photosensitive insulating layer formed on one surface of the base substrate and having a roughness formed on a surface thereof; and
a seed layer formed on one surface of the photosensitive insulating layer.

2. The substrate as set forth in claim 1, wherein the insulating layer further includes via holes formed for exposing connection pads on the base substrate.

3. The substrate as set forth in claim 1, wherein the roughness has a predetermined pattern.

4. The substrate as set forth in claim 1, wherein the roughness is formed by photolithography including exposing and developing processes.

5. The substrate as set forth in claim 1, wherein the seed layer includes a first seed layer and a second seed layer formed on the first seed layer.

6. The substrate as set forth in claim 5, wherein the first seed layer is a titanium (Ti) layer, a titanium-tungsten (TiW) layer, a titanium nitride (TiN) layer, a chromium (Cr) layer, a nickel (Ni) layer, an aluminum (Al) layer or an alloy layer thereof.

7. The substrate as set forth in claim 5, wherein the second seed layer is a copper (Cu) layer, a nickel (Ni) layer, a nickel vanadium (NiV) layer, or an alloy layer thereof.

8. The substrate as set forth in claim 1, further comprising a circuit pattern layer formed on the seed layer.

9. A method for manufacturing a substrate for a package, comprising:
preparing a base substrate;
forming a photosensitive insulating layer on the base substrate;
forming a roughness on a surface of the photosensitive insulating layer; and
forming a seed layer on the surface of the photosensitive insulating layer on which the roughness is formed.

10. The method as set forth in claim 9, wherein the forming the roughness includes forming via holes for exposing connection pads of the base substrate.

11. The method as set forth in claim 9, wherein the formed roughness has a predetermined pattern.

12. The method as set forth in claim 9, wherein the forming the roughness on the surface of the insulating layer includes:
disposing a mask having a pattern over the insulating layer; and
forming the roughness according to the pattern on the surface of the insulating layer by exposing and developing processes.

13. The method as set forth in claim 9, wherein the pattern includes a pattern for forming the roughness and a pattern for forming the via holes.

14. The method as set forth in claim 13, wherein the pattern for forming the roughness and the pattern for forming the via holes have different light transmittances.

15. The method as set forth in claim 9, wherein the seed layer includes a first seed layer and a second layer formed on the first seed layer.

16. The method as set forth in claim 15, wherein the first seed layer is a titanium (Ti) layer, a titanium-tungsten (TiW) layer, a titanium nitride (TiN) layer, a chromium (Cr) layer, a nickel (Ni) layer, an aluminum (Al) layer or an alloy layer thereof.

17. The method as set forth in claim 15, wherein the second seed layer is a copper (Cu) layer, a nickel (Ni) layer, a nickel vanadium (NiV) layer, or an alloy layer thereof.

18. The method as set forth in claim 9, wherein the seed layer is formed by sputtering.

19. The method as set forth in claim 9, further comprising forming a circuit pattern layer on the seed layer, after the forming the seed layer.
